(19) United States
(12) Patent Application Publication
(10) Pub. No.: US 2012/0025861 A1
(43) Pub. Date: Feb. 2, 2012

(54) TEST SOCKET AND TEST DEVICE HAVING THE SAME

(75) Inventors: Hwan Wook PARK, Yongin-si (KR); Woo Seop KIM, Seoul (KR); Sung Bum CHO, Yongin-si (KR)

(73) Assignee: SAMSUNG ELECTRONICS CO., LTD., Suwon-si (KR)

(21) Appl. No.: 13/196,380

(22) Filed: Aug. 2, 2011

(30) Foreign Application Priority Data
Aug. 2, 2010 (KR) 10-2010-0074490

(51) Int. Cl. G01R 31/00

(52) U.S. Cl. 324/756.02

(57) ABSTRACT

A test device is provided. The test device includes a first via which transmits a supply voltage, a second via which transmits a ground voltage, a test board including a plurality of test signal vias for transmitting a plurality of test signals, a capacitor disposed on an upper part of the test board and connected between the first via and the second via, and a test socket which electrically connects a device under test (DUT) with the test board. The test socket includes a first region including a flat lower surface bordering the test board, a second region including an uneven lower surface, a plurality of first contactors which are disposed in the first region and which are connected to the plurality of vias, and two second contactors which are disposed in the second region and which are connected to two terminals of the capacitor.

### CROSS-REFERENCE TO RELATED APPLICATION

This application claims priority under 35 U.S.C. §119 from Korean Patent Application No. 10-2010-0074490 filed on Aug. 2, 2010, the disclosure of which is hereby incorporated by reference in its entirety.

### BACKGROUND

1. Field

Embodiments of the present inventive concept relate to a test device, and more particularly, to a test device which may decrease power impedance in an intermediate frequency region and a high frequency region and improve power integrity while embodying a capacitor on an upper part of a test board.

2. Description of the Related Art

A semiconductor chip or an IC chip is assembled as a semiconductor package through a packaging process. Before an assembled semiconductor package is sent out as goods, a manufacturer inspects if an operation of the package is poor by using a test socket. The test socket is a device for connecting the semiconductor package to a test board electrically.

### SUMMARY

The present general inventive concept provides a test device improving a bandwidth by decreasing power impedance in an intermediate frequency region and a high frequency region.

An exemplary embodiment provides a test socket which electrically connects a device under test (DUT) and a test board, including a frame including a first region, which includes a flat lower surface bordering on the test board, and a second region including an uneven surface, a plurality of first contactors disposed in the first region and which supply a plurality of test signals output from the test board to the DUT, and a plurality of second contactors disposed in the second region and which supply a plurality of supplies output from the test board to the DUT.

A length of each of the plurality of first contactors is longer than a length of each of the plurality of second contactors.

According to an exemplary aspect, each of the plurality of first contactors and second contactors may be a Pogo pin.

According to another exemplary aspect, each of the plurality of first contactors and second contactors may be a conductive rubber.

Another exemplary embodiment provides a test device, including a test board including a first via which transmits a supply voltage, a second via which transmits a ground voltage, and a plurality of test signal vias for transmitting a plurality of test signals, a capacitor which is disposed on an upper part of the test board and which is connected between the first via and the second via, and a test socket which electrically connects a device under test (DUT) to the test board.

The test socket includes a frame, which includes a first region including a flat lower surface, and a second region including an uneven surface, a plurality of first contactors disposed in the first region, each of which is connected to one of the plurality of test signal vias, and two second contactors disposed in the second region, each of which is connected to a terminal of the capacitor.

Another exemplary embodiment provides a test socket which electrically connects a device under test (DUT) with a test board, including a lower region including a plurality of first contactors which are disposed to electrically contact the test board, an upper region including a plurality of second contactors which are disposed to electrically contact the DUT, and a printed circuit board (PCB) disposed between the upper region and the lower region and including a plurality of vias and a capacitor. Each of the terminals of the capacitor and each of the vias is connected to one of the plurality of first contactors and one of the plurality of second contactors.

According to another exemplary embodiment a test device is provided including a test board, a device under test (DUT) and a test socket electrically connecting the test board with the DUT.

The test socket includes a lower region including a plurality of first contactors which are electrically connected to the test board, an upper region including a plurality of second contactors which are electrically connected to the DUT, and a printed circuit board (PCB) which is disposed between the upper region and the lower region and which includes a plurality of vias and a capacitor. Each of the terminals of the capacitor and each of the vias is connected to one of the plurality of first contactors and one of the plurality of second contactors.

Each of the plurality of first contactors and each of the plurality of second contactors may be embodied in a conductive rubber.

### BRIEF DESCRIPTION OF THE DRAWINGS

These and/or other aspects and advantages of exemplary embodiments will become apparent and more readily appreciated from the following description, taken in conjunction with the accompanying drawings of which:

FIG. 1 shows a cross-sectional diagram of a test device including a test socket according to an exemplary embodiment;

FIG. 2 shows a cross-sectional diagram of a test device including a test socket according to another exemplary embodiment;

FIG. 3 shows a cross-sectional diagram of a test device including a test socket according to still another exemplary embodiment; and

FIG. 4 shows impedance according to changes of frequency.

### DETAILED DESCRIPTION OF THE PREFERRED EMBODIMENTS

Reference will now be made in detail to embodiments, examples of which are illustrated in the accompanying drawings, wherein like reference numerals refer to the like elements throughout. The exemplary embodiments are described below with reference to the figures.

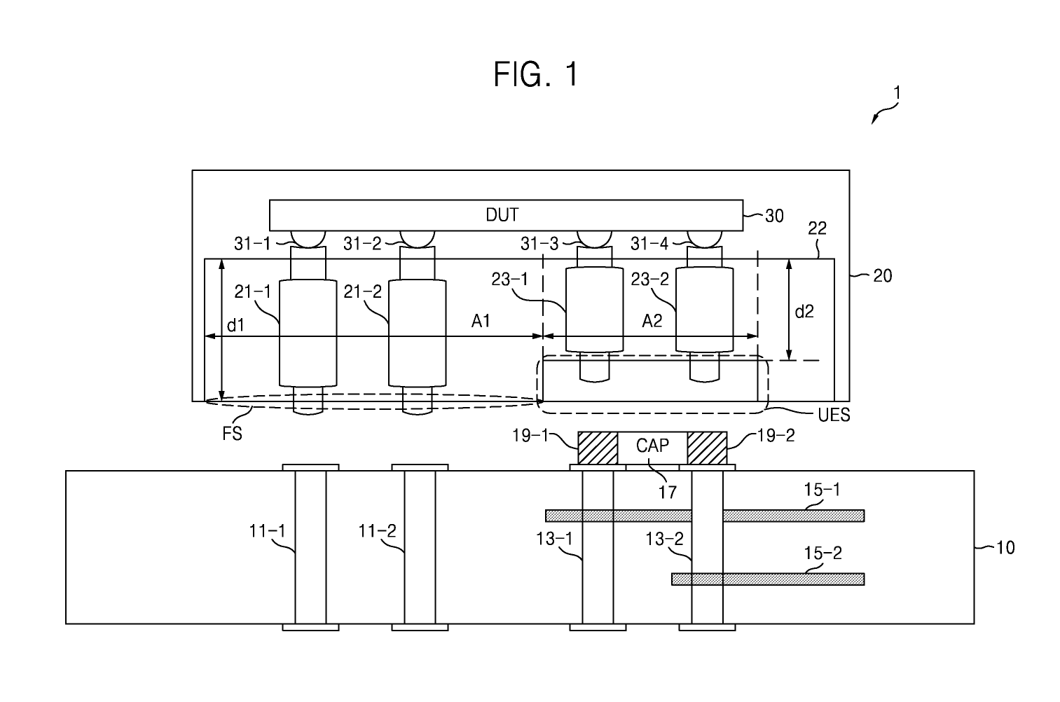

FIG. 1 shows a cross-sectional diagram of a test device including a test socket according to an exemplary embodiment. Referring to FIG. 1, a test device 1 includes a test board 10 and a test socket 20.

The test board 10 tests if a device under test (DUT) 30, e.g., a semiconductor package, operates or not by supplying a plurality of test signals and a plurality of supply voltages, e.g., a supply voltage and a ground voltage, to the DUT 30, a test object, through the test socket 20.

The test board 10 which may comprise a printed circuit board (PCB) includes a plurality of test signal vias 11-1 and 11-2 each for transmitting each of the plurality of test signals, a first via 13-1 for transmitting a supply voltage and a second via 13-2 for transmitting a ground voltage. The plurality of test signals, the supply voltage and the ground voltage may be signals output from a test (not shown) connected to the test board 10.

The first via 13-1 is connected to a supply voltage conductor (or a supply voltage pattern 15-1) electrically and the second via 13-2 is connected to a ground voltage conductor (or a ground voltage pattern 15-2) electrically. Here, a via is an example of a through hole conductor.

Each of a first terminal 19-1 and a second terminal 19-2 of a capacitor 17 disposed on an upper part of the test board 10 is electrically connected to an upper part of the first via 13-1 and an upper part of the second via 13-2, respectively. For example, the terminals 19-1 and 19-2 of the capacitor 17 may be connected to an upper part of the first via 13-1 and an upper part of the second via 13-2, respectively, by soldering.

The test socket 20 includes a contact support frame or a contactor 22 which may connect the test board 10 with the DUT 30. The contactor 22 includes a first region A1, which includes a flat surface FS formed on a lower part bordering on the test board 10, and a second region A2 including an uneven surface UES. Here, the uneven surface UES, e.g., an uneven part or a groove, may be as large as the capacitor 17, such that both terminals 19-1 and 19-2 of the capacitor 17 may be inserted into the uneven surface UES when the test board 10 and the test socket 20 are connected electrically or mechanically.

The plurality of first contactors 21-1 and 21-2 may be formed in the first region A1 of the contact support frame 22 having a first thickness d1. When each of the plurality of first contactors 21-1 and 21-2 electrically contacts or connects one of the plurality of test signal vias 11-1 and 11-2 with one of a plurality of first connection terminals 31-1 and 31-2 of the DUT 30, each of the plurality of first contactors 21-1 and 21-2 may supply one of a plurality of test signals output from the test board 10 to the DUT 30.

Each of a plurality of second contactor 23-1 and 23-2 may be formed in the second region A2 of the contact support frame 22 having a second thickness d2, which is smaller than d1. When each of the plurality of second contactors 23-1 and 23-2 electrically contacts or connects one of a first terminal 19-1 and a second terminal 19-2 of the capacitor 17 with one of a plurality of second connection terminals 31-3 and 31-4 of the DUT 30, each of the plurality of second contactors 23-1 and 23-2 may supply a supply voltage or a ground voltage output from the test board 10 to the DUT 30.

Each of the plurality of first contactors 21-1 and 21-2 and each of the plurality of second contactors 23-1 and 23-2 may comprise a Pogo pin. As each of the plurality of first contactors 21-1 and 21-2 is disposed in the first region A1 having the first thickness d1 and each of the plurality of second contactors 23-1 and 23-2 is disposed in the second region A2 having the second thickness d2, the length of each of the plurality of first contactors 21-1 and 21-2 may longer than the length of each of the plurality of second contactors 23-1 and 23-2.

A structure and a material of each of the plurality of first connection terminals 31-1 and 31-2 and second connection terminals 31-3 and 31-4 may be changed according to a packaging method of the DUT 30. Here, a connection terminal may be a pin or a pad.

For example, when the DUT 30 is a ball grid array (BGA) type, each of the plurality of first connection terminals 31-1 and 31-2 and each of the plurality of second connection terminals 31-3 and 31-4 may comprise a solder ball.

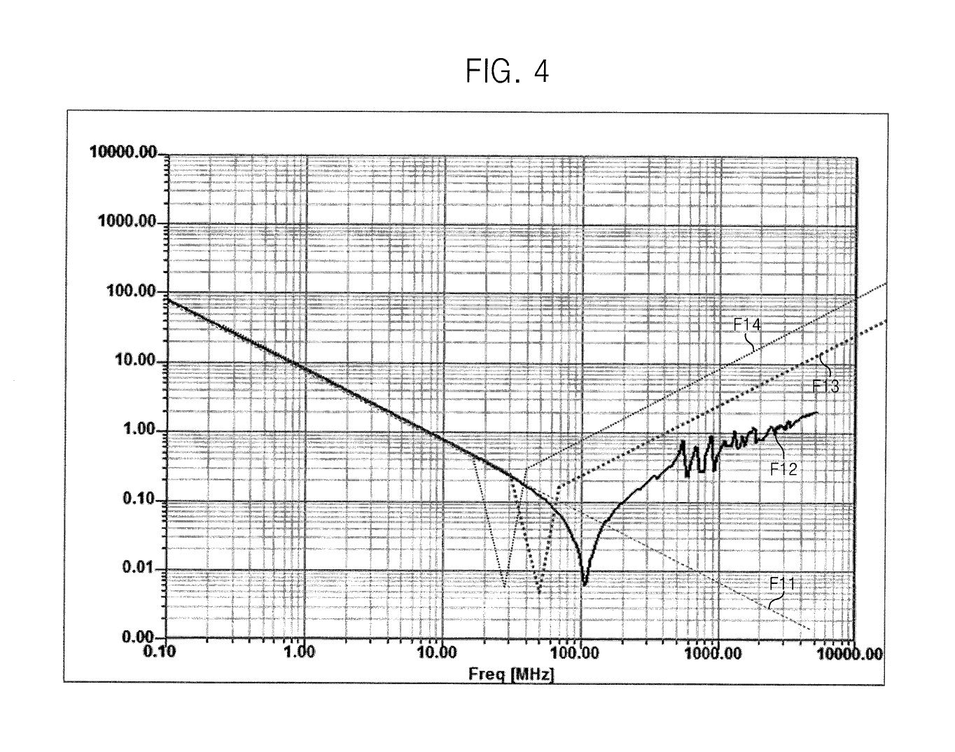

When the DUT 30 is installed or inserted into the contact support frame 22 of the test socket 20 including housing, that is, when the DUT 30 is electrically connected to the test board 10 through the contact support frame 22 of the test socket 20, power noise output through a connection terminal 31-3 may be fed back to a connection terminal 31-4 through the capacitor 17. Accordingly, since the return path of the power noise becomes shorter when the capacitor 17 is disposed on the upper part of the test board 10, power integrity may be improved in an intermediate frequency region and a high frequency region as illustrated in FIG. 4. To perform a test for the DUT 30, the DUT 30 installed on or inserted into the test socket 20 is illustrated in FIG. 1.

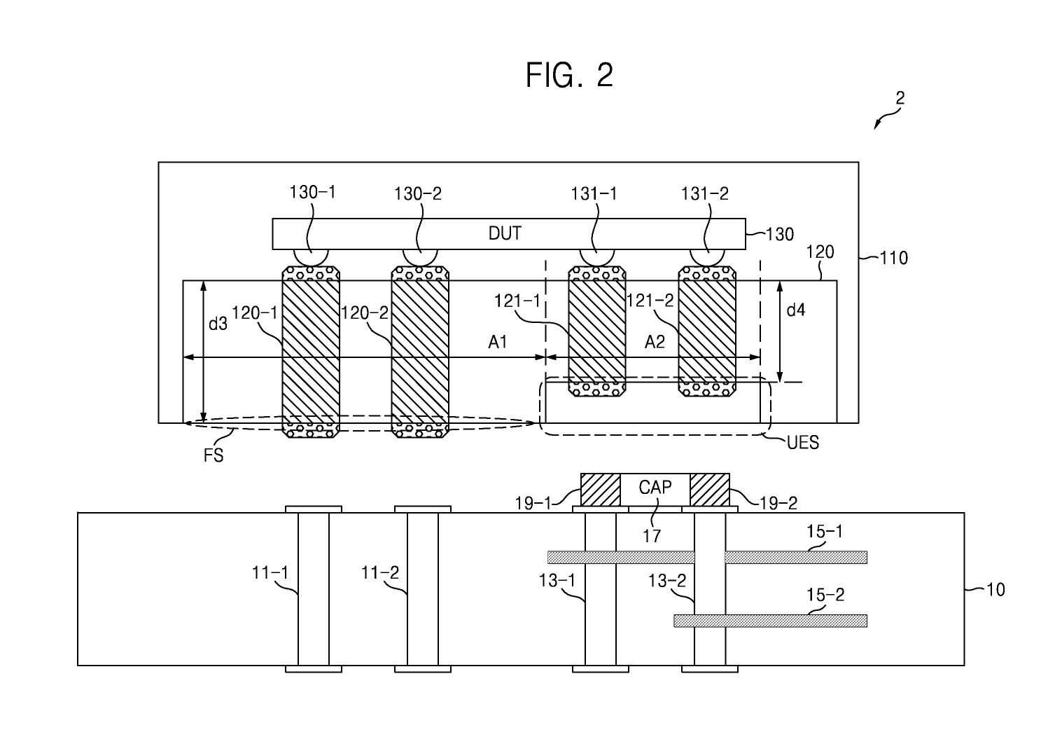

FIG. 2 shows a cross-sectional diagram of a test device including a test socket according to another exemplary embodiment. Referring to FIG. 2, the test device 2 includes the test board 10 and the test socket 110. The structure of the test board 10 illustrated in FIG. 1 is substantially the same as that of the test board 10 illustrated in FIG. 2.

The test socket 110 includes a first region A1, which includes a flat surface FS formed on a lower part bordering on the test board 10, and a second region A2 including an uneven surface UES. As described above, the uneven surface UES is as large as the capacitor 17, such that both terminals 19-1 and 19-2 of the capacitor 17 may be inserted into the uneven surface UES when the test board 10 and the test socket 110 are connected to each other.

A plurality of first contactors 120-1 and 120-2 may be disposed in a first region A1 of a contact support frame or a contactor 120 having a third thickness d3. When each of the plurality of first contactors 120-1 and 120-2 electrically contacts or connects one of a plurality of test signal vias 11-1 and 11-2 with one of a plurality of first connection terminals 130-1 and 130-2 of the DUT 130, each of the plurality of first contactors 120-1 and 120-2 may supply one of a plurality of test signals output from the test board 10 to the DUT 130.

Each of a plurality of second contactors 121-1 and 121-2 may be disposed in the second region A2 of the contact support frame 120 having a fourth thickness d4, which is smaller than d3. When each of the plurality of second contactors 121-1 and 121-2 electrically contacts or connects one of a first terminal 19-1 and a second terminal 19-2 of the capacitor 17 with one of a plurality of second connection terminals 131-1 and 131-2 of the DUT 130, each of the plurality of second contactors 121-1 and 121-2 may supply one of a supply voltage and a ground voltage output from the test board 10 to the DUT 130.

Each of the plurality of first contactors 120-1 and 120-2 and each of the plurality of second contactors 121-1 and 121-2 may comprise a conductive material, e.g., a conductive rubber, which may shrink or expand.

Each of the plurality of first contactors 120-1 and 120-2 is formed in the first region A1 having the third thickness d3, and each of the plurality of second contactors 121-1 and 121-2 is formed in the second region A2 having the fourth thickness d4. Thus, the length of each of the plurality of first contactors 120-1 and 120-2 may be longer than the length of each of the plurality of second contactors 121-1 and 121-2.

A structure and a material of each of the plurality of first connection terminals 130-1 and 130-2 and second connection terminals 131-1 and 131-2 may be changed according to a packaging method of the DUT 130.

When the DUT 130 is installed on or inserted into the contact support frame 122 of the test socket 110 including housing, that is, when the DUT 130 is electrically connected to the test board 10 through the contact support frame 122 of the test socket 110, power noise output through a connection terminal 131-1 may be fed back to a connection terminal 131-2 through the capacitor 17. Accordingly, since the return path of the power noise gets shorter when the capacitor 17 is disposed on an upper part of the test board 10, power integrity in an intermediate frequency region and a high frequency region may be improved as illustrated in FIG. 4.

The DUT 130 installed on or inserted into the test socket 110 is illustrated in FIG. 2 to perform a test on the DUT 130.

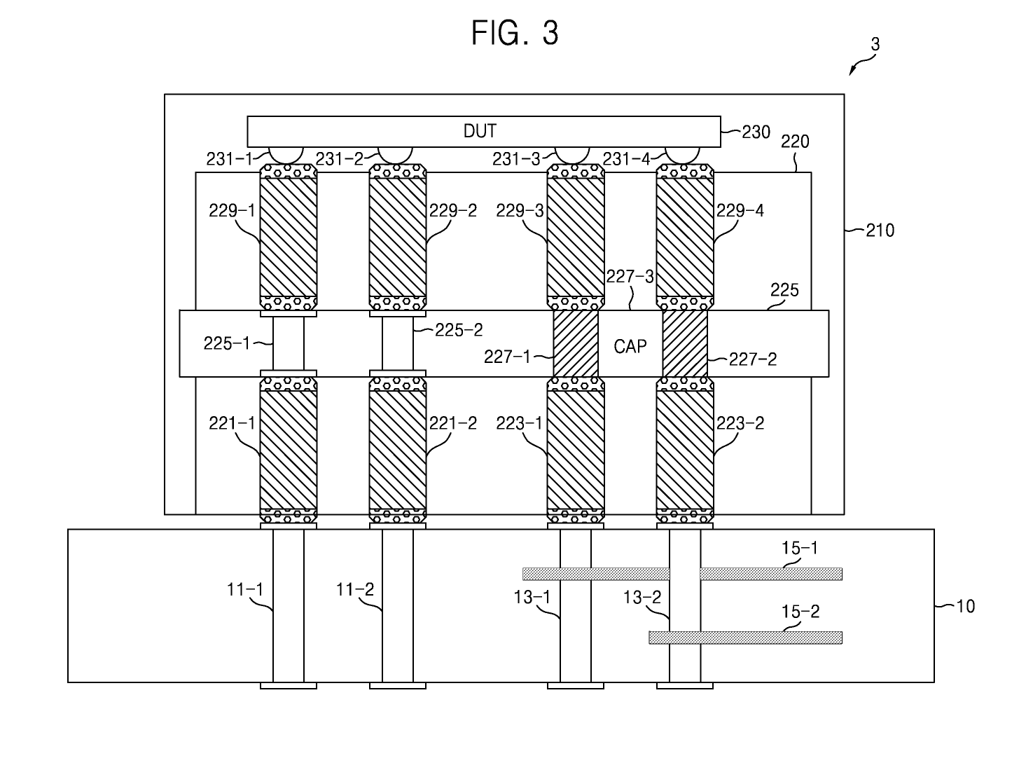

FIG. 3 displays a cross-sectional diagram of a test device including a test socket according to still another exemplary embodiment. Referring to FIG. 3, a test device 3 includes a test board 10 and a test socket 210. A structure of the test board 10 illustrated in FIG. 3 is substantially the same as that of the test board 10 illustrated in FIG. 1, except that the capacitor is not disposed on the upper part of the test board 10 in FIG. 3.

A test socket 220 for connecting a DUT 230 with the test board 10 electrically, e.g., a contact support frame or a contactor 220, includes a lower region including a plurality of first contactors 221-1, 221-2, 223-1 and 223-2, an upper region including a plurality of second contactors 229-1, 229-2, 229-3 and 229-4, and a PCB 225 which may be inserted between the lower region and the upper region. The PCB 225 may be separated from the test socket 220.

Each of the plurality of first contactors 221-1, 221-2, 223-1 and 223-2 formed in the lower region electrically contacts one a the plurality of vias 11-1, 11-2, 13-1 and 13-2 formed in the test board 10.

Each of the plurality of second contactors 229-1, 229-2, 229-3 and 229-4 formed in the upper region is electrically connected to one of a plurality of connection terminals 231-1, 231-2, 231-3 and 231-4 formed in the DUT 230. The PCB 225 inserted between the lower region and the upper region includes a plurality of vias 225-1 and 225-2, and a capacitor 227-3.

A via 225-1 is connected between corresponding contactors 221-1 and 229-1, a via 225-2 is connected between corresponding contactors 221-2 and 229-2, a first terminal 227-1 of a capacitor 227-3 is connected between corresponding contactors 223-1 and 229-3, and a second terminal 227-2 of the capacitor 227-3 is connected between corresponding contactors 223-2 and 229-4.

Each of the plurality of first contactors 221-1, 221-2. 223-1 and 223-2 and each of the plurality of second contactors 229-1, 229-2, 229-3 and 229-4 may comprise a conductive material, e.g., a conductive rubber, which may shrink or expand.

When the DUT 230 is installed on or inserted into the test socket 220, that is, when the test board 10 and the DUT 230 are electrically connected to each other by the contact support frame 220 of the test socket 220, power noise output through the connection terminal 231-3 may be fed back to the connection terminal 231-4 through the capacitor 227-3. Accordingly, since a return path of the power noise becomes shorter when the capacitor 227-3 is disposed inside the PCB 225 of the test board 210, power integrity in an intermediate or a high frequency may be improved.

FIG. 4 displays impedance according to a change of frequency. Referring to FIG. 4, frequency is shown on the horizontal axis and an absolute value of impedance is shown on the vertical axis. F11 indicates the impedance of an ideal capacitor according to a change in frequency, and F12 indicates the impedance of a real capacitor according to a change in frequency. The real capacitor includes a resistor component connected in series, an inductor component and a capacitor component, so that it may have a serial resonant frequency.

F13 indicates the impedance (hereinafter, it is also called power impedance) which may be determined in connection terminals 31-3, 131-1 or 231-1 for a supply voltage of the DUT 30, 130 or 230 when the capacitor 17 or 227-3 used for bypass is disposed on an upper part of the test board 10 or inside the PCB 225 which may be inserted into the test socket 220, and the test board 10, the test socket 20, 110 or 210 and the DUT 30, 130 or 230 are electrically connected to each other.

The power impedance may mean power impedance seen toward the contact support frame 22, 120 or 220 at the connection terminal 31-3, 131-1 or 231-1 for a supply voltage.

F14 indicates power impedance determined at the connection terminal 31-3, 131-1 or 231-1 for a supply voltage of the DUT 30, 130 or 230 when a capacitor used for bypass is connected between vias 13-1 and 13-2 on a lower part of the test board 10, and the test board 10 and the DUT 30, 130 or 230 are electrically connected to each other by the test socket 20, 110, or 210.

As illustrated in FIGS. 1 and 2, a return path of power noise becomes shorter when the capacitor 17 is disposed on an upper part of the test board 10, and effects of inductance caused by a first via 13-1 and effects of inductance caused by a supply voltage conductor 15-1 may be eliminated from the power impedance. Accordingly, power impedance marked as F13 in an intermediate and a high frequency region becomes smaller than power impedance marked as F14 as illustrated in FIG. 4.

In addition, when a capacitor 227-3 is disposed inside the PCB 225 which may be inserted into the contact support frame 220 as illustrated in FIG. 3, a return path of power noise becomes shorter, and effects of inductance caused by the first via 13-1 and effects of inductance caused by the supply voltage conductor 15-1 may be eliminated from the power impedance. Accordingly, power impedance marked as F13 in an intermediate and a high frequency region becomes smaller than power impedance marked as F14 as illustrated in FIG. 4.

A test device 1, 2 or 3 according to exemplary embodiments may eliminate effects of inductance caused by the first via 13-1 and effects of inductance caused by the supply voltage conductor 15-1 from the power impedance in a connection terminal for a supply voltage, e.g., 31-3, 131-1 or 231-3 by disposing the capacitor 17 or 227-3 closely to the connection terminal, e.g., 31-1, 131-1 or 231-3 for a supply voltage.

Accordingly, since the power impedance in an intermediate frequency region and a high frequency region decreases, a bandwidth increases. Moreover, power integrity of a test device 1, 2 or 3 including a test socket 20, 110 or 210 may be improved. For example, a size of the capacitor 17 or 227-3 may be equal or similar to pitch of the connection terminal 31-3, 131-1 or 231-3 of a DUT 30, 130, or 230.

A test device according to exemplary embodiments described herein may reduce power impedance in an intermediate frequency region and a high frequency region and improve power integrity.

Although a few exemplary embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A test socket for a semiconductor memory device which electrically connects a device under test (DUT) with a test board, the test socket comprising:
a frame comprising a first region comprising a flat lower surface, and a second region comprising an uneven lower surface;
a plurality of first contactors which are disposed in the first region and which supply a plurality of test signals output from the test board to the DUT; and
a plurality of second contactors which are disposed in the second region and which supply a plurality of voltages output from the test board to the DUT.

2. The test socket of claim 1, wherein a length of each of the plurality of first contactors is longer than a length of each of the plurality of second contactors.

3. The test socket of claim 1, wherein each of the plurality of first contactors and each of the plurality of second contactors comprises is a Pogo pin.

4. The test socket of claim 1, wherein each of the plurality of first contactors and each of the plurality of second contactors comprises a conductive rubber.

5. A test device for a semiconductor memory device comprising:
a test board comprising a first via which transmits a supply voltage, a second via which transmits a ground voltage and a plurality of test signal vias which transmit a plurality of test signals;
a capacitor which is disposed on an upper portion of the test board and which is connected between the first via and the second via; and
a test socket which electrically connects a device under test (DUT) with the test board,
wherein the test socket comprises:
a frame comprising a first region comprising a flat lower surface, and a second region comprising an uneven lower surface;
a plurality of first contactors which are disposed in the first region, wherein each of the plurality of first contactors is connected to one of the plurality of test signal vias; and
two second contactors which are disposed in the second region, each of which is connected to a terminal of the capacitor.

6. The test device of claim 5, wherein a length of each of the plurality of first contactors is longer than a length of each of the two second contactors.

7. The test device of claim 5, wherein each of the plurality of first contactors and each of the two second contactors comprises a Pogo pin.

8. The test device of claim 5, wherein each of the plurality of first contactors and each of the two second contactors comprises a conductive rubber.

9. A test socket for a semiconductor memory device which electrically connects a device under test (DUT) with a test board, the test socket comprising:
a lower region comprising a plurality of first contactors which are disposed to electrically contact the test board;
an upper region comprising a plurality of second contactors which are disposed to electrically contact the DUT; and
a printed circuit board (PCB) which is disposed between the upper region and the lower region, and which comprises a plurality of vias and a capacitor comprising two terminals,
wherein each of the terminals of the capacitor and each of the vias is connected to one of the plurality of first contactors and one of the plurality of second contactors.

10. The test socket of claim 9, wherein each of the plurality of first contactors and each of the plurality of second contactors comprises a conductive rubber.

11. A test device for a semiconductor memory device comprising:
a test board;
a device under test (DUT); and
a test socket which electrically connects the test board to the DUT,
wherein the test socket comprises:
a lower region comprising a plurality of first contactors which are electrically connected to the test board;
an upper region comprising a plurality of second contactors which are electrically connected to the DUT; and
a printed circuit board (PCB) which is disposed between the upper region and the lower region, and which comprises a plurality of vias and a capacitor comprising two terminals,
wherein each of the terminals of the capacitor and each of the vias is connected to one of the plurality of first contactors and one of the plurality of second contactors.

12. The test device of claim 11, wherein each of the plurality of first contactors and each of the plurality of second contactors comprises a conductive rubber.

13. (canceled)

14. (canceled)
